(19) United States
(12) Patent Application Publication
(10) Pub. No.: US 2016/0293570 A1
(43) Pub. Date: Oct. 6, 2016

(54) ELECTRONIC CONNECTION STRUCTURE FOR COUPLING PINS OF CHIP WITH WIRING CIRCUIT AND PANEL USING SAME

(71) Applicant: HON HAI PRECISION INDUSTRY CO., LTD., New Taipei (TW)

(72) Inventor: CHIH-FANG CHEN, Tu-Cheng (TW)

(21) Appl. No.: 14/825,554

(22) Filed: Aug. 13, 2015

(30) Foreign Application Priority Data
Mar. 31, 2015 (TW) 104110584

(51) Int. Cl. H01L 23/00

(52) U.S. Cl. CPC H01L 24/92; H01L 24/33; H01L 24/49; H01L 24/73; H01L 24/83; H01L 24/85; H01L 2224/33106; H01L 2224/4918; H01L 2224/73215; H01L 2224/83851; H01L 2224/92147

(57) ABSTRACT

An electronic connection structure includes a first connection portion, a second connection portion, and a connection pad configured to be coupled the first connection portion to the second connection. The connection pad includes a connection layer and at least two conduction layers. The connection layer is configured to be coupled to the first connection portion via anisotropic conductive media. The conduction layers are configured to be coupled the connection layer to the second connection portion. The at least two conduction layers are partially overlapped.

### CROSS-REFERENCE TO RELATED APPLICATIONS

This application claims priority to Taiwanese Patent Application No. 104110584 filed on Mar. 31, 2015, the contents of which are incorporated by reference herein.

### FIELD

The subject matter herein generally relates to an electronic connection structure for coupling pins of a chip with wiring circuit and a panel using the electronic connection structure.

### BACKGROUND

Electronic connection structures are widely used in all kinds of electronic device, such as display panels. A display panel, such as a liquid crystal display panel or an organic light emitting diode display panel, includes various wirings, such as a plurality of scan lines for providing scanning signals to pixels of the display panel, a plurality of date lines for providing image data signals to the pixels of the display panel, and a plurality of extending lines for connecting ends of the data lines or ends of the scan lines to connection pads located in a peripheral area of the display panel, and a chip bonded on a peripheral area of the display panel. The chip is used to generate the data signals and the scanning signals to drive the display panel. The electronic connection structure is used to couple pins of the chip to these wirings.

### BRIEF DESCRIPTION OF THE DRAWINGS

Implementations of the present technology will now be described, by way of example only, with reference to the attached figures.

FIG. 1 is a schematic view of a present embodiment of an electronic connection structure used in a display panel.

FIG. 2 is a cross-sectional view of FIG. 1, taking along line II-II.

FIG. 3 is a cross-sectional view of FIG. 1, taking along line III-III.

FIG. 4 is a cross-sectional view of FIG. 1, taking along line IV-IV.

FIG. 5 is a cross-sectional view of FIG. 1, taking along line V-V.

FIG. 6 illustrates that a first conduction layer and a second conduction layer of the electronic connection structure of FIG. 1 partially overlap.

FIG. 7 is a schematic view of another embodiment of an electronic connection structure with a resolution higher than the electronic connection structure of FIG. 1.

### DETAILED DESCRIPTION

It will be appreciated that for simplicity and clarity of illustration, where appropriate, reference numerals have been repeated among the different figures to indicate corresponding or analogous elements. In addition, numerous specific details are set forth in order to provide a thorough understanding of the embodiments described herein. However, it will be understood by those of ordinary skill in the art that the embodiments described herein can be practiced without these specific details. In other instances, methods, procedures and components have not been described in detail so as not to obscure the related relevant feature being described. Also, the description is not to be considered as limiting the scope of the embodiments described herein. The drawings are not necessarily to scale and the proportions of certain parts may be exaggerated to better illustrate details and features of the present disclosure.

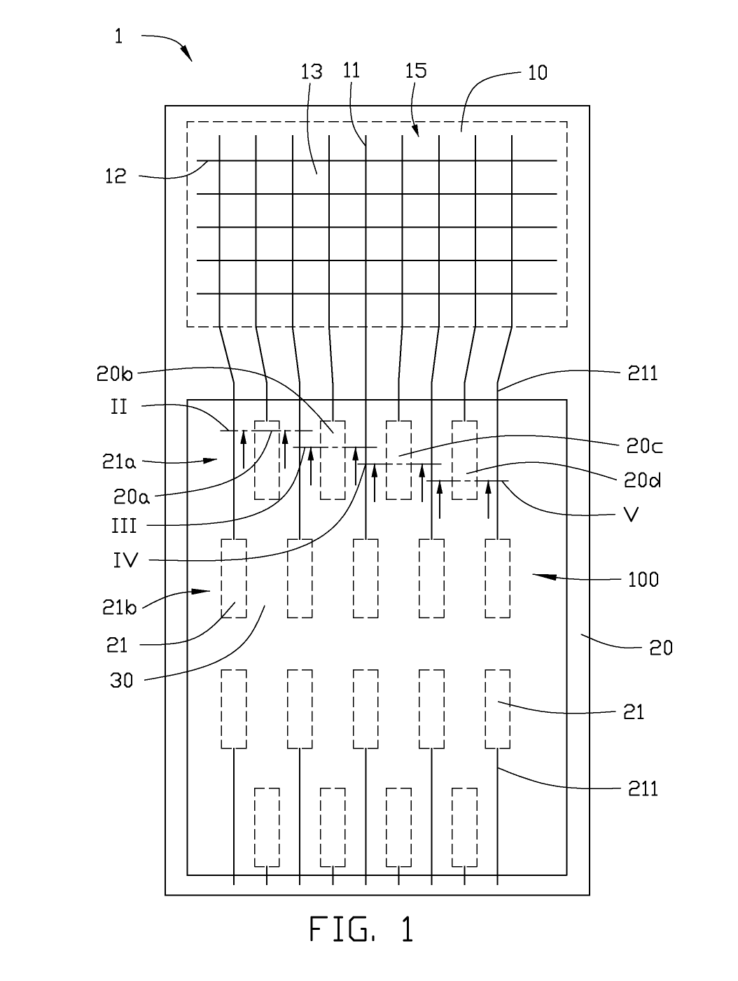

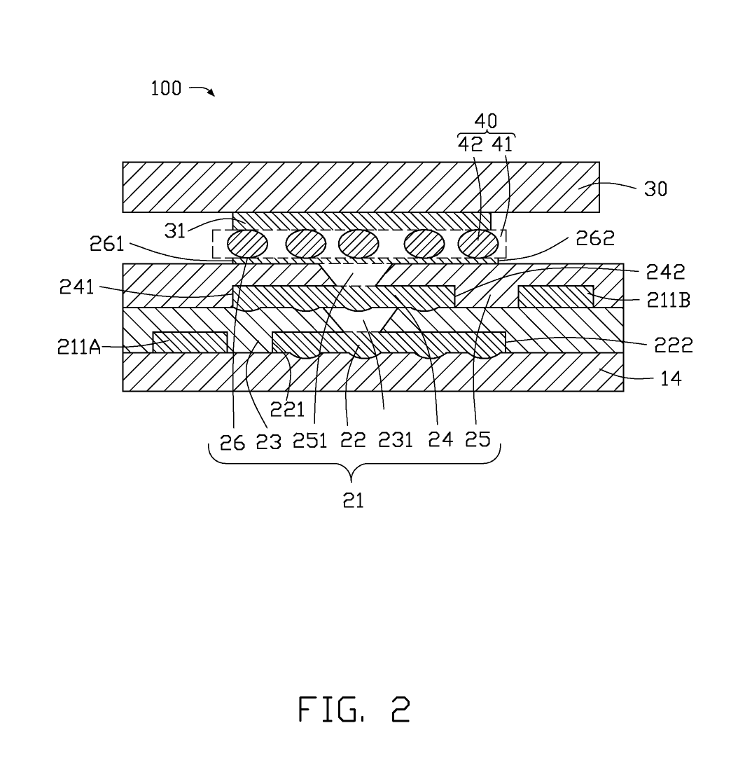

FIG. 1 is a diagrammatic view of an embodiment of an electronic connection structure 100 used in a panel 1, such as a liquid crystal display (LCD) display panel, an organic light emitting diode (OLED) display panel, a touch panel or the like. For describing the structure more clearly, units in FIG. 1 have not drawn according to a normal ratio or scale. In at least one embodiment, the panel 1 is a display panel. As illustrated in FIG. 1 and FIG. 2, the display panel 1 includes a substrate layer 14, a wiring circuit 15, an integrated circuit 30, and the electronic connection structure 100 formed on the substrate layer 14. The substrate layer 14 may be made of glass. The electronic connection structure 100 is electrically coupled to the integrated circuit 30 and the wiring circuit 15. The integrated circuit 30 may be a chip, which can be, but not limited, a driver integrated circuit (IC) used for driving the display panel 1.

The display panel 1 may further include a display area 10 and a non-display area 20. The display area 10 is an area configured to display an image. The non-display area 20 is an area set around the display area 10. The wiring circuit 15 may be include a plurality of first driving lines 11 and a plurality of second driving lines 12, which are disposed at the display area 10. The first driving lines 11 are parallel each other. The second driving lines 12 are parallel with each other. The first driving lines 11 are insulated from the second driving lines 12. In at least one embodiment, the first driving lines 11 are scan lines, and the second driving lines 12 are date lines. A plurality of pixels 13 are defined by the first driving lines 11 and the second driving lines 12.

The electronic connection structure 100 is formed at the non-display area 20. The integrated circuit 30 is bonded to the electronic connection structure 100 and corresponds to the electronic connection structure 100. The electronic connection structure 100 includes a plurality of connection pads 21 and a plurality of connection wires 211. The integrated circuit 30 transmits signals to the display area 10 via some of the connection pads 21, and the connection wires 211 are connected to the connection pads 21 and configured to transmit signals. In at least one embodiment, the connection pads 21 are connected with pins 31 of the integrated circuit 30 by anisotropic conductive adhesive (ACF) 40. The connection wires 211 are directly connected with the connection pads 21 for transmitting signals. In at least one embodiment, some of the connection wires 211 extend to the display area 10 and are further connected with the first driving lines 11 or the second driving lines 12 of the wiring circuit 15 via the corresponding connection pads 21. Some of the connection wires 211 extend outwardly to connect to an external circuit (not shown), such as a flexible circuit board (FPC).

The connection pads 21 are arranged in two parallel lines to be divided into a first connection pad group 21a and a second connection pad group 21b. The connection pads 21 arranged in a line in the first connection pad group 21a are more adjacent to the wiring circuit 15 than the connection pads 21 arranged in a line in the second connection pad group 21b. The connection pads 21 in the first connection pad group 21 a and the connection pads 21 in the second connection pad group 21b are arranged alternately. The connection pad 21 in the first connection pad group 21a is sandwiched between two adjacent connection wires 211 coupled to the connection pad 21 in the second connection pad group 21b.

Each of the connection pads 21 includes a first conduction layer 22, a first insulation layer 23, a second conduction layer 24, a second insulation layer 25, and a connection layer 26. The first conduction layer 22 is formed on the substrate layer 14. The first insulation layer 23 covers the substrate layer 14 and the first conduction layer 22. The second conduction layer 24 is formed on the first insulation layer 23. The second insulation layer 25 covers the first insulation layer 23 and the second conduction layer 24. The connection layer 26 is formed on the second insulation layer 25. A first connection hole 231 is defined in the first insulation layer 23. A second connection hole 251 is defined in the second insulation layer 25. Some conductive materials are formed in the first connection hole 231 and the second connection hole 251. The first conduction layer 22 is coupled to the second conduction layer 24 via the conductive materials in the first connection hole 231. The second conduction layer 24 is coupled to the connection layer 26 via the conductive materials in the second connection hole 251.

In at least one embodiment, the first conduction layer 22 and the second conduction layer 24 are nontransparent conductive layers, which can be made of, for example but not limited, aluminum, molybdenum, cuprum, titanium, chromium, gold, silver, or compound of aluminum, molybdenum, cuprum, titanium, chromium, gold, and silver. The connection layer 26 is a transparent conductive layer, which can be made of, for example but not limited, transparent conducting oxides, such as indium tin oxide (ITO) and indium zinc oxide (IZO).

The first conduction layer 22 and at least one connection wire 211 are located on the substrate layer 14. The second conduction layer 24 and at least one connection wire 211 are located on the first insulation layer 23. The first conduction layer 22 includes a right border 222 and a left border 221. The second conduction layer 24 includes a right border 242 and a left border 241. The connection layer 26 includes a right border 262 and a left border 261.

One of the right border 222 of the first conduction layer 22 and the right border 242 of the second conduction layer 24 is aligned with or extended beyond the right border 262 of the connection layer 26. One of the left border 221 of the first conduction layer 22 and the left border 241 of the second conduction layer 24 is aligned with or extended beyond the left border 261 of the connection layer 26. A border of each of the first conduction layer 22 and the second conduction layer 24 adjacent to a connection wire 211 is aligned or not extended beyond a border of the connection layer 26 at the same side with the border of the connection pad 21. The first conduction layer 22 and the second conduction layer 24 partially overlap.

The connection pads 21 in the first connection pad group 21a and the connection wires 211 at two sides of the connection pads 211 define a first portion 20a, a second portion 20b, a third portion 20c, and a fourth portion 20d. As illustrated in FIG. 2, in the first portion 20a, the connection wire 211A on the left side of the connection pad 21 is located on the substrate layer 14, and the connection wire 211B on the right side of the connection pad 21 is located on the first insulation layer 23. The right border 222 of the first conduction layer 22 is aligned with or extended beyond the right border 262 of the connection layer 26. The left border 241 of the second conduction layer 24 is aligned with or extended beyond the left border 261 of the connection layer 26.

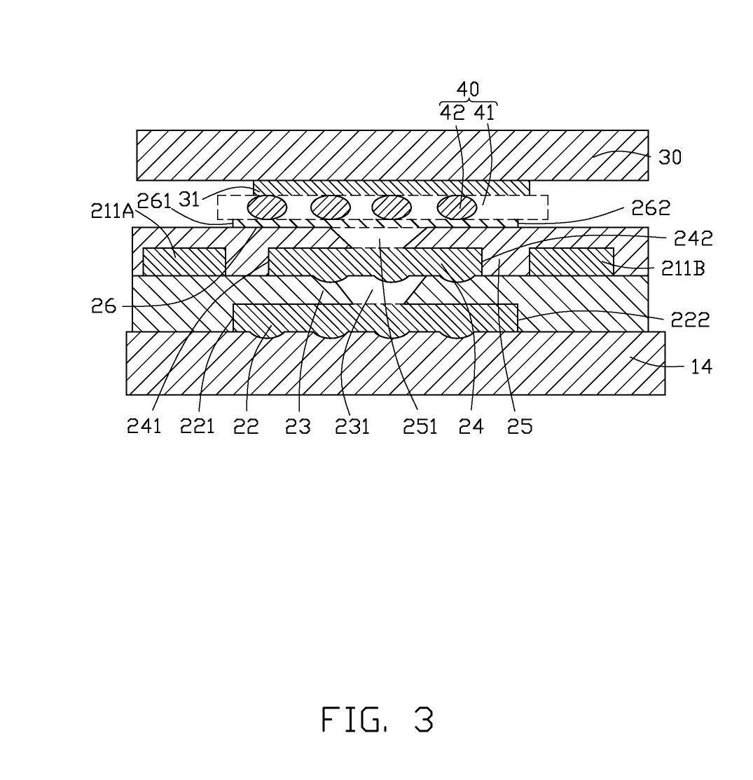

As illustrated in FIG. 3, in the second portion 20b, the connection wire 211A on the right side and the left side of the connection pad 21 are both on the first insulation layer 23. The right border 222 of the first conduction layer 22 is aligned with or extended beyond the right border 262 of the connection layer 26. The left border 221 of the first conduction layer 22 is aligned with or extended beyond the left border 261 of the connection layer 26.

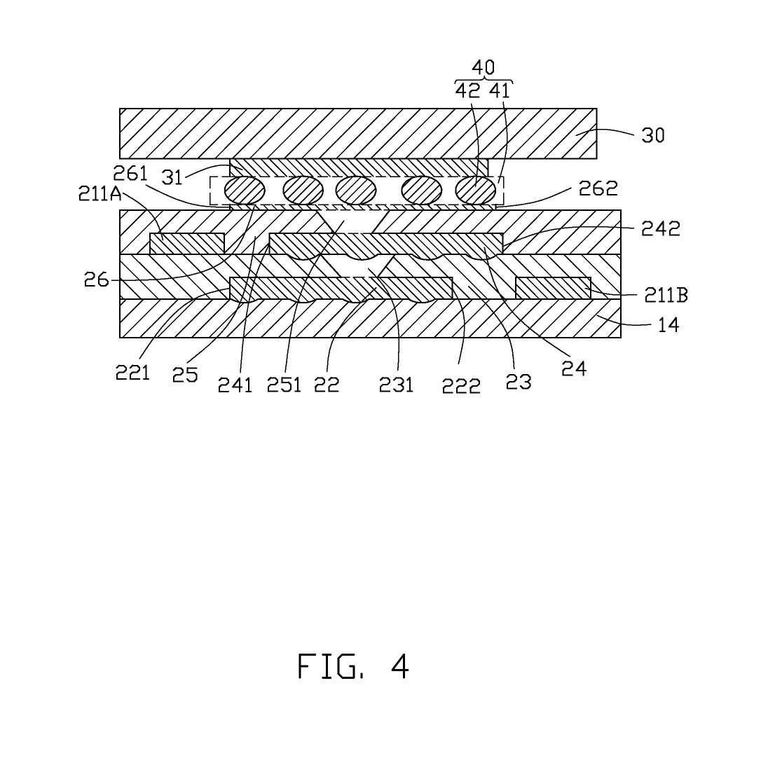

As illustrated in FIG. 4 in the third portion 20c, the connection wire 211A on the left side of the connection pad 21 is located on the first insulation layer 23, and the connection wire 211B on the right side of the connection pad 21 is located on the substrate layer 14. The right border 242 of the second conduction layer 24 is aligned with or extended beyond the right border 262 of the connection layer 26. The left border 221 of the first conduction layer 22 is aligned with or extended beyond the left border 261 of the connection layer 26.

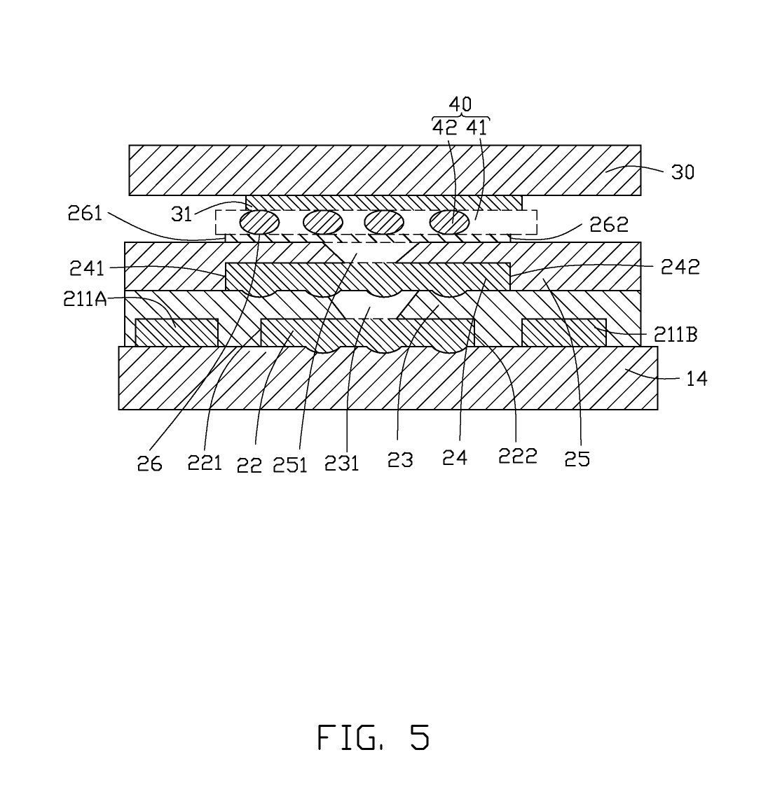

As illustrated in FIG. 5, in the fourth portion 20d, the connection wire 211A on the right side and the left side of the connection pad 21 are both on the substrate layer 14. The right border 242 of the second conduction layer 24 is aligned with or extended beyond the right border 262 of the connection layer 26. The left border 241 of the second conduction layer 24 is aligned with or extended beyond the left border 261 of the connection layer 26.

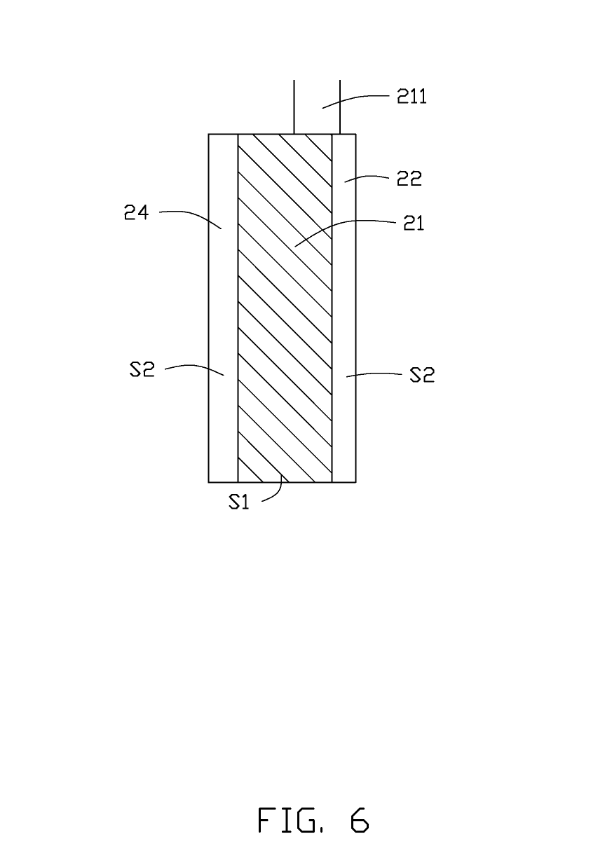

As illustrated in FIG. 6, in a direction vertical to the structure 100, the first conduction layer 22 and the second conduction layer 24 partially overlap. A sum area of non-overlapped areas S2 of the first conduction layer 22 and the second conduction layer 24 is not less than a quarter of an overlapped area S1.

The anisotropic conductive media 40 includes an adhesive 42 containing a plurality of conducting particles 41. The anisotropic conductive media 40 is formed on the connection pad 21. The integrated circuit 30 is disposed on the anisotropic conductive media 40. After the integrated circuit 30 is disposed on the anisotropic conductive media 40, the integrated circuit 30 presses the anisotropic conductive media 40 via a pressure applied on the integrated circuit 30. The conducting particles 41 of the anisotropic conductive media 40 are coupled to the connection pads 21 and the pins 31 simultaneously.

When the connection pads 21 and the pins 31 are coupled by the anisotropic conductive media 40, the conducting particles 41 will make indentations on the first conduction layer 22 and the second conduction layer 24. An operator can determine whether the connection pads 21 and the pins 31 are good coupled via observing the indentations. When the first conduction layer 22 and the second conduction layer 24 partially overlap, a total width of the first conduction layer 22 and the second conduction layer 24 is increased. More indentations will be generated on the first conduction layer 22 and the second conduction layer 24, and thus a probability of wrong determination whether the connection pads 21 and the pins 31 are good coupled is reduced.

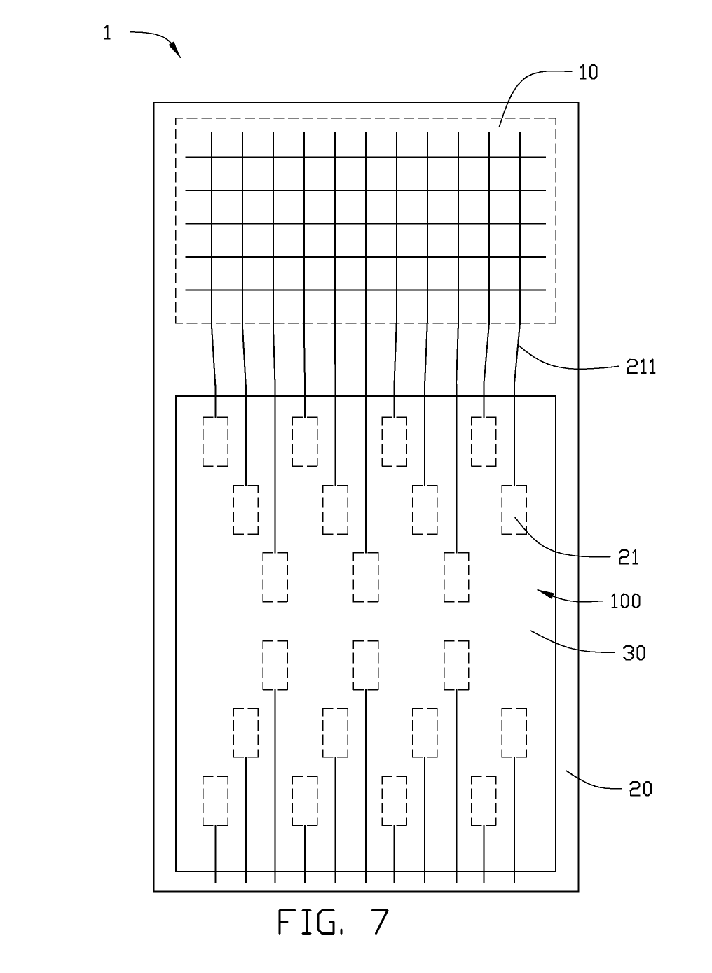

As illustrated in FIG. 7, in a higher resolution display panel 1 using the electronic connection structure 100. The conductive pads 21 in the electronic connection structure 100 are arranged in three or more paralleled lines to be divided into a plurality of connection pad groups. As long as the conduction layers of the connection pads partially overlap, a total width of the conduction layers is improved. More indentations will be generated on the conduction layers, and thus a probability of wrong determination whether the connection pads and the pins are good coupled will be reduced.

The embodiments shown and described above are only examples. Many details are often found in the art such as the other features of a structure and a panel using the structure. Therefore, many such details are neither shown nor described. Even though numerous characteristics and advantages of the present technology have been set forth in the foregoing description, together with details of the structure and function of the present disclosure, the disclosure is illustrative only, and changes may be made in the detail, especially in matters of shape, size and arrangement of the parts within the principles of the present disclosure up to, and including the full extent established by the broad general meaning of the terms used in the claims. It will therefore be appreciated that the embodiments described above may be modified within the scope of the claims.

1. An electronic connection structure, comprising:
a first connection portion;
a second connection portion coupled to the first connection portion;
a plurality of connection pads formed on a substrate layer and configured to couple the first connection portion to the second connection portion, each connection pad comprising:
a first conduction layer formed on the substrate layer;
a first insulation layer covering the substrate layer and the first conduction layer, a first connection hole being defined in the first insulation layer;
a second conduction layer formed on the first insulation layer;
a second insulation layer covering the first insulation layer and the second conduction layer, a second connection hole being defined in the second insulation layer, the second conduction layer being electrically coupled to the first conduction layer via conductive materials in the first connection hole; and
a connection layer formed on the second insulation layer and electrically coupled to the second conduction layer via conductive materials in the second connection hole;
the connection layer being to be electrically coupled to the first connection portion by an anisotropic conductive media;
the first conduction layer and the second conduction layer configured to cooperate with each other to couple the first connection portion to the second connection portion, wherein the second conduction layer partially overlaps the first conduction layer; and
wherein a first border of at least one of the first conduction layer and the second conduction layer is aligned with or extended beyond a first border of the connection layer, and a second border of at least one of the first conduction layer and the second conduction layer is aligned with or extended beyond a second border of the connection layer.

2. The electronic connection structure of claim 1, wherein the electronic connection structure further comprises a plurality of connection wires, each of the connection wires configures to couple one of the first conduction layer and the second conduction layer to the second connection portion.

3-4. (canceled)

5. The electronic connection structure of claim 2, wherein at least one of the connection wires is disposed on the substrate, and other connection wires are disposed on the first insulation layer.

6. The electronic connection structure of claim 2, wherein the connection wires comprise a first connection wire located at a first side of one of the connection pads and a second connection wire located at a second side of the connection pad, the first connection wire is located on the substrate, the second connection wire is located on the first insulation layer, a second border of the first conduction layer is aligned with or extended beyond a second border of the connection layer, a first border of the second conduction layer is aligned with or extended beyond a first border of the connection layer.

7. The electronic connection structure of claim 2, wherein the connection wires comprise a first connection wire located at a first side of one of the connection pads and a second connection wire located at a second side of the connection pad, the first connection wire and the second connection wire are both located on the first insulation layer, a second border of the first conduction layer is aligned with or extended beyond a second border of the connection layer, a first border of the first conduction layer is aligned with or extended beyond a first border of the connection layer.

8. The electronic connection structure of claim 2, wherein the connection wires comprise a first connection wire located at a first side of one of the connection pads and a second connection wire located at a second side of the connection pad, the first connection wire is located on the first insulation layer, the second connection wire is located on the substrate, a second border of the second conduction layer is aligned with or extended beyond a second border of the connection layer, a first border of the first conduction layer is aligned with or extended beyond a first border of the connection layer.

9. The electronic connection structure of claim 2, wherein the connection wires comprise a first connection wire located at a first side of one of the connection pads and a second connection wire located at a second side of the connection pad, the first connection wire and the second connection wire are both located on the substrate, a second border of the second conduction layer is aligned with or extended beyond a second border of the connection layer, a first border of the second conduction layer is aligned with or extended beyond a first border of the connection layer.

10. The electronic connection structure of claim 1, wherein the first conduction layer and the second conduction layer cooperatively define a overlapped area and two non-overlapped areas, a sum area of non-overlapped areas is not less than a quarter of the overlapped area.

11. A panel, comprising:
a wiring circuit configured to execute functions;
a chip configured to control the wiring circuit coupled to the wiring circuit;
a plurality of connection pads formed on a substrate layer and configured to couple the chip to the wiring circuit, each connection pad comprising:
a first conduction layer formed on the substrate layer;
a first insulation layer covering the substrate layer and the first conduction layer, a first connection hole being defined in the first insulation layer;
a second conduction layer formed on the first insulation layer;
a second insulation layer covering the first insulation layer and the second conduction layer, a second connection hole being defined in the second insulation layer, the second conduction layer being electrically coupled to the first conduction layer via conductive materials in the first connection hole; and
a connection layer formed on the second insulation layer and electrically coupled to the second conduction layer via conductive materials in the second connection hole;
the connection layer being electrically coupled to the chip by an anisotropic conductive media;
the first conduction layer and the second conduction layer configured to cooperate with each other to couple the chip to the wiring circuit, wherein the second conduction layer partially overlaps the first conduction layer; and
wherein a first border of at least one of the first conduction layer and the second conduction layer is aligned with or extended beyond a first border of the connection layer, and a second border of at least one of the first conduction layer and the second conduction layer is aligned with or extended beyond a second border of the connection layer.

12. The panel of claim 11, wherein the electronic connection structure further comprises a plurality of connection wires, each of the connection wires configures to couple one of the first conduction layer and the second conduction layer to the wiring circuit.

13-14. (canceled)

15. The panel of claim 12, wherein at least one of the connection wires is disposed on the substrate, and other connection wires are disposed on the first insulation layer.

16. The panel of claim 12, wherein the connection wires comprise a first connection wire located at a first side of one of the connection pads and a second connection wire located at a second side of one of the connection pads, the first connection wire is located on the substrate, the second connection wire is located on the first insulation layer, a second border of the first conduction layer is aligned with or extended beyond a second border of the connection layer, a first border of the second conduction layer is aligned with or extended beyond a first border of the connection layer.

17. The panel of claim 12, wherein the connection wires comprise a first connection wire located at a first side of one of the connection pads and a second connection wire located at a second side of one of the connection pads, the first connection wire and the second connection wire are both located on the first insulation layer, a second border of the first conduction layer is aligned with or extended beyond a second border of the connection layer, a first border of the first conduction layer is aligned with or extended beyond a first border of the connection layer.

18. The panel of claim 12, wherein the connection wires comprise a first connection wire located at a first side of one of the connection pads and a second connection wire located at a second side of the connection pad, the first connection wire is located on the first insulation layer, the second connection wire is located on the substrate, a second border of the second conduction layer is aligned with or extended beyond a second border of the connection layer, a first border of the first conduction layer is aligned with or extended beyond a first border of the connection layer.

19. The panel of claim 12, wherein the connection wires comprise a first connection wire located at a first side of one of the connection pads and a second connection wire located at a second side of the connection pad, the first connection wire and the second connection wire are both located on the substrate, a second border of the second conduction layer is aligned with or extended beyond a second border of the connection layer, a first border of the second conduction layer is aligned with or extended beyond a first border of the connection layer.

20. The panel of claim 11, wherein the first conduction layer and the second conduction layer cooperatively define a overlapped area and two non-overlapped areas, a sum area of non-overlapped areas is not less than a quarter of the overlapped area.
